(19) United States
(12) Patent Application Publication
(10) Pub. No.: US 2013/0344285 A1
(43) Pub. Date: Dec. 26, 2013

(54) ADHESIVE MATERIAL USED FOR JOINING CHAMBER COMPONENTS

(71) Applicants: Jennifer Y. Sun, Mountain View, CA (US); Sumanth Banda, San Jose, CA (US)

(72) Inventors: Jennifer Y. Sun, Mountain View, CA (US); Sumanth Banda, San Jose, CA (US)

(73) Assignee: APPLIED MATERIALS, INC., Santa Clara, CA (US)

(21) Appl. No.: 13/988,656

(22) PCT Filed: Nov. 7, 2011
(86) PCT No.: PCT/US2011/059625

§ 371 Date: May 21, 2013

Related U.S. Application Data
(60) Provisional application No. 61/413,807, filed on Nov. 15, 2010.

(51) Int. Cl. B32B 7/12; H01L 21/02; B32B 9/00; B32B 3/26; B32B 9/04

(52) U.S. Cl. CPC B32B 7/12; B32B 3/266; B32B 9/041; B32B 9/005; H01L 21/02
USPC 428/137; 556/465; 428/220; 428/447

(57) ABSTRACT

Embodiments of the invention provide a robust bonding material suitable for joining semiconductor processing chamber components. Other embodiments provide semiconductor processing chamber components joined using an adhesive material with desired characteristics. In one embodiment, an adhesive material suitable for joining semiconductor chamber components includes an adhesive material having a Young's-modulus lower than 300 psi. In another embodiment, a semiconductor chamber component includes a first surface disposed adjacent a second surface, and an adhesive material coupling the first and second surfaces, wherein the adhesive material has a Young's modulus lower than 300 psi.

### BACKGROUND OF THE INVENTION

1. Field of the Invention

Embodiments of the invention generally relate to a semiconductor processing chamber, more specifically, to an adhesive material suitable for joining semiconductor processing chamber components.

2. Description of the Related Art

Semiconductor processing involves a number of different chemical and physical processes whereby minute integrated circuits are created on a substrate. Layers of materials which make up the integrated circuit are created by chemical vapor deposition, physical vapor deposition, epitaxial growth, and the like. Some of the layers of material are patterned using photoresist masks and wet or dry etching techniques. The substrate utilized to form integrated circuits may be silicon, gallium arsenide, indium phosphide, glass, or any other appropriate materials.

A typical semiconductor processing chamber may have many components. Some components include a chamber body defining a process zone, a gas distribution assembly adapted to supply a process gas from a gas supply into the process zone, a gas energizer, e.g., a plasma generator, utilized to energize the process gas within the process zone, a substrate support assembly, and a gas exhaust. Some components may be comprised of an assembly of parts. For example, a showerhead assembly may include a conductive base plate adhesively bonded to a ceramic gas distribution plate. Effective bonding of the parts requires a suitable adhesive and a unique bonding technique to ensure that the parts are securely attached to each other while compensating for any mismatch in thermal expansion and without adversely creating any interfacial defects.

Therefore, there is a need for a robust adhesive material utilized to assemble parts and/or components in a semiconductor processing chamber.

### SUMMARY OF THE INVENTION

Embodiments of the invention provide a robust adhesive material suitable for joining semiconductor processing chamber components. In one embodiment, an adhesive material suitable for joining semiconductor chamber components includes an adhesive material having a Young's modulus lower than 300 psi.

In another embodiment, a semiconductor chamber component includes a first surface disposed adjacent a second surface, and an adhesive material coupling the first and second surfaces, wherein the adhesive material has a Young's modulus lower than 300 psi.

In yet another embodiment, a method for bonding semiconductor processing chamber components includes applying an adhesive material on a surface of a first component, wherein the adhesive material has a Young's modulus lower than 300 psi, coupling a second component to the surface of the first component through contact with the adhesive material, and thermally processing the adhesive layer coupling the first and the second component.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1 depicts a sectional view of one embodiment of a processing chamber using a bonding material according the present invention;

FIG. 2 depicts a sectional view of one embodiment with substrates being bound by an adhesive material according the present invention; and

FIG. 3 depicts an exploded sectional view of one embodiment with substrates being bound by a perforated sheet of adhesive material according the present invention.

It is to be noted, however, that the appended drawings illustrate only typical embodiments of this invention and are therefore not to be considered limiting of its scope, for the invention may admit to other equally effective embodiments.

To facilitate understanding, identical reference numerals have been used, wherever possible, to designate identical elements that are common to the figures. It is contemplated that elements of one embodiment may be advantageously utilized in other embodiments without further recitation.

### DETAILED DESCRIPTION

Embodiments of the invention provide a robust adhesive material for joining parts utilized in a semiconductor processing chamber, processing chamber components bonded with the inventive adhesive material and methods for fabricating the same. In one embodiment, the robust bonding material is a silicone based material having certain desired adhesive material characteristics so as to provide a good bonding interface for bonding parts in gas distribution assembly or other different assemblies of a semiconductor processing chamber. The adhesive material has a desired range of thermal expansion coefficient, thermal stress, elongation and thermal conductivity so as to provide robust bonding between bonding components utilized in harsh plasma etching environments and the like.

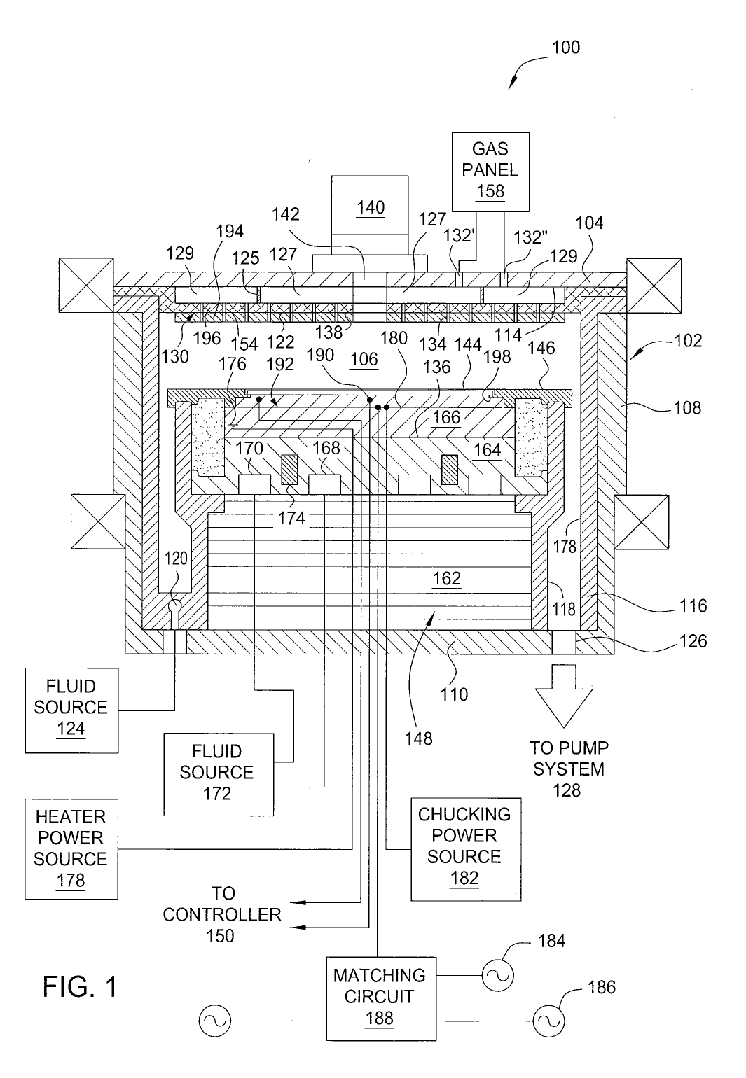

FIG. 1 is a sectional view of one embodiment of a semiconductor processing chamber 100 having at least one component utilizing a bonding material according to the present invention. One examples of suitable processing chamber 100 may be a CENTURA® ENABLER™ Etch System, available from Applied Materials, Inc of Santa Clara, Calif. It is contemplated that the other processing chambers may be adapted to benefit from one or more of the inventive techniques disclosed herein.

The processing chamber 100 includes a chamber body 102 and a lid 104 which enclose an interior volume 106. The chamber body 102 is typically fabricated from aluminum, stainless steel or other suitable material. The chamber body 102 generally includes sidewalls 108 and a bottom 110. A substrate access port (not shown) is generally defined in a side wall 108 and is selectively sealed by a slit valve to facilitate entry and egress of the substrate 144 from the processing chamber 100. An outer liner 116 may be positioned against on the side walls 108 of the chamber body 102. The outer liner 116 may be fabricated and/or coated with a plasma or halogen-containing gas resistant material. In one embodiment, the outer liner 116 is fabricated from aluminum oxide. In another embodiment, the outer liner 116 is fabricated from or coated with Yttrium, Yttrium alloy or an oxide thereof. In yet another embodiment, the outer liner 116 is fabricated from bulk Y₂O₃.

An exhaust port 126 is defined in the chamber body 102 and couples the interior volume 106 to a pump system 128. The pump system 128 generally includes one or more pumps and throttle valves utilized to evacuate and regulate the pressure of the interior volume 106 of the processing chamber 100. In one embodiment, the pump system 128 maintains the pressure inside the interior volume 106 at operating pressures typically between about 10 mTorr to about 20 Torr.

The lid 104 is sealingly supported on the side wall 108 of the chamber body 102. The lid 104 may be opened to allow excess to the interior volume 106 of the processing chamber 100. The lid 104 may optionally include a window 142 that facilitates optical process monitoring. In one embodiment, the window 142 is comprised of quartz or other suitable material that is transmissive to a signal utilized by an optical monitoring system 140. One optical monitoring system that may be adapted to benefit from the invention is the EyeD® full-spectrum, interferometric metrology module, available from Applied Materials, Inc., of Santa Clara, Calif.

A gas panel 158 is coupled to the processing chamber 100 to provide process and/or cleaning gases to the interior volume 106. Examples of processing gases may include halogen-containing gas, such as C₂F₆, SF₆, SiCl₄, HBr, NF₃, CF₄, Cl₂, CHF₃, CF₄, and SiF₄, among others, and other gases such as O₂, or N₂O. Examples of carrier gases include N₂, He, Ar, other gases inert to the process and non-reactive gases. In the embodiment depicted in FIG. 1, inlet ports 132′, 132″ (collectively ports 132) are provided in the lid 104 to allow gases to be delivered from the gas panel 158 to the interior volume 106 of the processing chamber 100 through a gas distribution assembly 130.

The gas distribution assembly 130 is coupled to an interior surface 114 of the lid 104. The gas distribution assembly 130 includes a gas distribution plate 194 coupled to a conductive base plate 196. The conductive base plate 196 may serve as an RF electrode. In one embodiment, the conductive base plate 196 may be fabricated by aluminum, stainless steel or other suitable materials. The gas distribution plate 194 may be fabricated from a ceramic material, such as silicon carbide, bulk Yttrium or oxide thereof to provide resistance to halogen-containing chemistries. Alternatively, the gas distribution plate 194 may be coated with Yttrium or an oxide thereof to extend the life time of the gas distribution assembly 130.

The conductive base plate 196 is bonded to the gas distribution plate 194 by an adhesive material 122 according to the present invention. The adhesive material 122 may be applied to the lower surface of the conductive base plate 196 or the upper surface of the gas distribution plate 194 to mechanically bond the gas distribution plate 194 to the conductive base plate 196. In one embodiment, the adhesive material 122 is a silicone based material that has certain desired characteristics that provide a robust bonding interface between the gas distribution plate 194 and the conductive base plate 196. The adhesive material 122 provides a bonding energy sufficient to securely join the conductive base plate 196 and the gas distribution plate 194. The bonding material 122 additionally provides a thermal conductivity sufficient to provide good heat transfer between the gas distribution plate 194 and the conductive base plate 196 compliant enough to prevent delamination due to thermal expansion mismatch between the gas distribution plate 194 and the conductive base plate 196 when heated during plasma processing. It is contemplated that the adhesive material 122 may also be used to bond other parts and/or components utilized to assemble the gas distribution assembly 130. In one embodiment, the layer of adhesive material 122 includes a plurality of adhesive rings and/or a plurality of adhesive beads or grooving as needed to separate independent zones of gas delivery through the gas distribution plate 194.

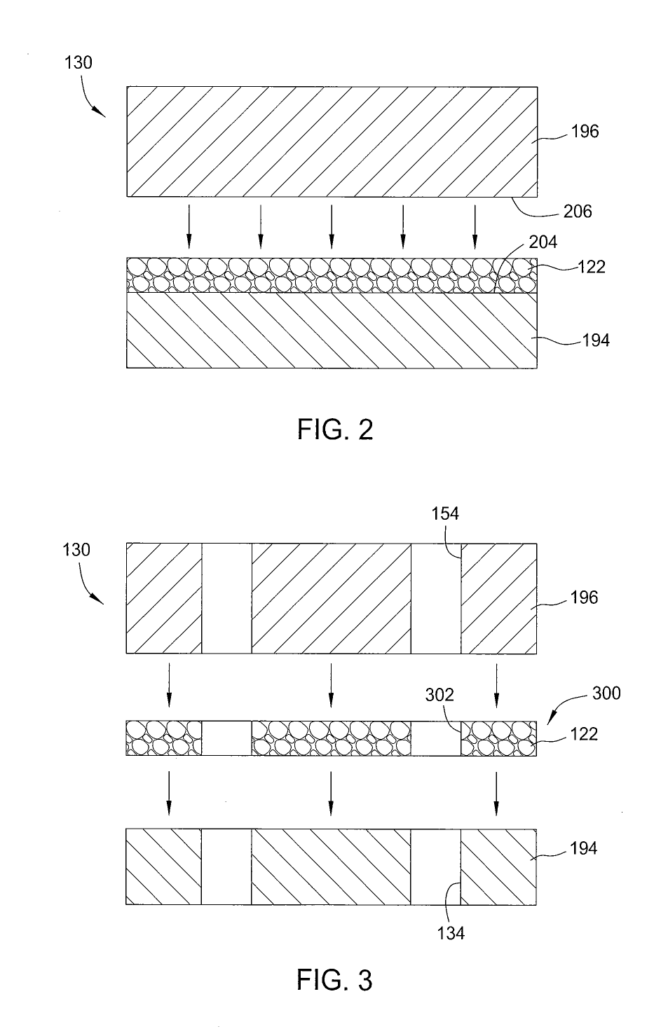

In one embodiment, the adhesive material 122 may be a thermal conductive paste, glue, gel or pad having desired selected characteristics to promote bonding energy between the bonded components, which will be described further below with referenced to FIG. 2. The adhesive materials may be applied to the interface in form of an adhesive ring, adhesive beads, or the combination thereof. The gas distribution plate 194 may be a flat disc having a plurality of apertures 134 formed in the lower surface of the gas distribution plate 194 facing toward the substrate 144. The apertures 134 of the gas distribution plate 194 align with corresponding apertures 154 formed through the conductive base plate 196 to allow the gases to flow from the inlet port 132 (shown as 132′, 132″) through one or more plenums (shown as 127, 129) into the interior volume 106 of the processing chamber 100 in a predefined distribution across the surface of the substrate 144 being processed in the chamber 100.

The gas distribution assembly 130 may includes dividers 125 disposed between the lid 104 and the conductive base plate 196 that define an inner plenum 127 and an outer plenum 129. The inner plenum 127 and the outer plenum 129 formed in the gas distribution assembly 130 may assist in preventing the mixing of gases provided from the gas panel prior to passing through the gas distribution plate 194. When dividers 125 are used, a corresponding of adhesive layer 122 is disposed between the gas distribution plate 194 and the conductive base plate 196 to isolate the gases provided from each inlet ports 132′, 132″ prior to passing through the gas distribution plate 194 and into the interior volume 106. Furthermore, the gas distribution assembly 130 may further include a region transmissive or passage 138 suitable for allowing the optical monitoring system 140 to view the interior volume 106 and/or substrate 144 positioned on the substrate support assembly 148. The passage 138 includes a window 142 to prevent gas leakage from the passage 138.

A substrate support assembly 148 is disposed in the interior volume 106 of the processing chamber 100 below the gas distribution assembly 130. The substrate support assembly 148 holds the substrate 144 during processing. The substrate support assembly 148 generally includes a plurality of lift pins (not shown) disposed therethrough that are configured to lift the substrate 144 from the support assembly 148 and facilitate exchange of the substrate 144 with a robot (not shown) in a conventional manner. An inner liner 118 may be coated on the periphery of the substrate support assembly 148. The inner liner 118 may be a halogen-containing gas resistant material which is substantially similar to material used for the outer liner 116. In one embodiment, the inner liner 118 may be fabricated from the same material as that of the outer liner 116. The inner liner 118 may include an internal conduit 120 through which a heat transfer fluid is provided from a fluid source 124 to regulate the temperature of the

In one embodiment, the substrate support assembly 148 includes a mounting plate 162, a base 164 and an electrostatic chuck 166. The mounting plate 162 is coupled to the bottom 110 of the chamber body 102 includes passages for routing utilities, such as fluids, power lines and sensor leads, among other, to the base 164 and chuck 166.

At least one of the base 164 or chuck 166 may include at least one optional embedded heater 176, at least one optional embedded isolator 174 and a plurality of conduits 168, 170 to control the lateral temperature profile of the support assembly 148. The conduits 168, 170 are fluidly coupled to a fluid source 172 that circulates a temperature regulating fluid therethrough. The heater 176 is regulated by a power source 178. The conduits 168, 170 and heater 176 are utilized to control the temperature of the base 164, thereby heating and/or cooling the electrostatic chuck 166. The temperature of the electrostatic chuck 166 and the base 164 may be monitored using a plurality of temperature sensors 190, 192. The electrostatic chuck 166 may further comprise a plurality of gas passages (not shown), such as grooves, that are formed in a substrate supporting surface of the chuck 166 and fluidly coupled to a source of a heat transfer (or backside) gas, such as He. In operation, the backside gas is provided at controlled pressure into the gas passages to enhance the heat transfer between the electrostatic chuck 166 and the substrate 144.

The electrostatic chuck 166 comprises at least one clamping electrode 180 controlled using a chucking power source 182. The electrode 180 (or other electrode disposed in the chuck 166 or base 164) may further be coupled to one or more RF power sources 184, 186 through a matching circuit 188 for maintaining a plasma formed form process and/or other gases within the processing chamber 100. The sources 184, 186 are generally capable of producing an RF signal having a frequency from about 50 kHz to about 3 GHz and a power of up to about 10,000 Watts.

The base 164 is secured to the electrostatic chuck 166 by a bonding material 136, which may be substantially similar or the same as the bonding material 122 utilized to bond the gas distribution plate 194 and the conductive base 196 in the gas distribution assembly 130. As described above, the bonding material 136 facilitates thermal energy exchange between the electrostatic chuck 166 and the base 164 and compensates for the thermal expansion mismatch therebetween. In one exemplary embodiment, the bonding material 136 mechanically bonds the electrostatic chuck 166 to base 164. It is contemplated that the bonding material 136 may also be used to bond other parts and/or components utilized to assemble the substrate support assembly 148, such as bonding the base 164 to the mounting plate 162.

FIG. 2 depicts a sectional view of one embodiment of an adhesive material 122 (or material 136) utilized to bond a first surface 204 to a second surface 206. The surfaces 204, 206 may be defined on the gas distribution plate 194 and the conductive base plate 196 formed in the gas distribution assembly 130, other components utilized in the substrate support assembly 148, or other chamber components as needed. In one embodiment, the adhesive material 122 may be the adhesive material 122 utilized to bond the gas distribution plate 194 to the conductive base plate 196 in the gas distribution assembly 130, as shown in FIG. 1.

The adhesive material 122 may be in the form of a gel, glue, pad or paste. Some examples of suitable adhesive material include, but not limited to, acrylic and silicone based compounds. In another embodiment, suitable examples may include acrylic, urethane, polyester, polycaprolactone (PCL), polymethylmethacrylate (PMMA), PEVA, PBMA, PHEMA, PEVAc, PVAc, Poly N-Vinyl pyrrolidone, Poly (ethylene-vinyl alcohol), resin, polyurethane, plastic or other polymer adhesive materials.

In one embodiment, the adhesive material 122 is selected to have a low Young's modulus, for example, less than 300 psi. Adhesive materials with low Young's modulus are comparatively complaint and can accommodate the surface variation at the bonding interface during the plasma process. During plasma processing, the surfaces at the interface may expand due to the thermal energy generated at the plasma reaction. Accordingly, the adhesive material 122 disposed at the interface is sufficiently complaint to accommodate the thermal expansion mismatch at the interface when the two surfaces 204, 206 are comprised of two different materials, e.g., the ceramic gas distribution plate 194 and the metallic conductive base plate 196. Therefore, the adhesive material 122 with low Young's modulus provides low thermal stress during the plasma process, thereby providing a desired degree of compliance to accommodate thermal expansion mismatch at the interface. In one embodiment, the adhesive material is selected to have a thermal stress less than about 2 MPa.

Furthermore, the adhesive material 122 is selected to have a high elongation, for example, greater than about 150 percent having a high thermal conductivity, for example, between about 0.1 W/mK and about 5.0 W/mK. Elongation of the adhesive material 122 may be measured by tensile test. High thermal conductivity of the adhesive material 122 may assist transmitting thermal energy between ceramic gas distribution plate 194 and the metallic conductive base plate 196 so as to maintain a uniform thermal heat transfer across the gas distribution assembly 130. Additionally, high thermal conductivity of the adhesive material 122 also assists transmitting thermal energy to the interior volume 106 of the processing chamber 100 to provide a uniform thermal gradient in the interior volume 106 so as to assist uniform distribution of the plasma during processing.

In one embodiment, the adhesive material 122 has a thickness selected sufficient to allow the first surface 204 and the second surface 206 to be securely bonded which being sufficient compliant. In one embodiment, the thickness of the adhesive material 122 is selected between about 100 μm and about 500 μm. A final gap between the bonded components may be controlled at between about 25 μm and about 500 μm. The adhesive material 122 may be applied as a sheet having a surface flatness less than 50 μm to ensure close tolerance and good parallelism between the surfaces 204, 206.

In one embodiment, as discussed above with referenced to FIG. 1, the adhesive material 122 may be in form of a perforated sheet material, circular rings with different dimensions, concentric rings or a mesh as desired. After the first surface 204 and the second surface 206 are bonded by the adhesive material 122, a thermal process, such as a baking, annealing, heat soaking, or other suitable heat process, may be performed to assist bonding of adhesive material 122 between the first surface 204 and the second surface 206. After bonding by the adhesive layer, the interface of the first surface 204 and the second surface 206 is substantially flat having a surface uniformity profile less than 100 μm.

FIG. 3 depicts an exploded view of one embodiment gas distribution assembly 130 having the adhesive material 122 in the form of a perforated sheet 300. The perforated sheet 300 may have the dimensional and physical characteristics as the adhesive material 122 described above. The perforated sheet 300 may have a disk shape and may have substantially the same diameter as the gas distribution plate 194. The perforated sheet 300 includes a plurality of pre-formed apertures 302 which are located to align with the apertures 134, 154. The plurality of apertures 302 may be arranged on a regular pattern, such as a grid, polar array, or radially pattern, among others. The diameters of the apertures 134, 154, 302 are substantially equal or with the diameters of the apertures 302 being slightly greater than diameters of the apertures 134, 154 so that the flow through the gas distribution assembly 130 has minimal restriction. Additionally, as the apertures 134, 154, 302 are concentric circles with little or no difference in diameter, there is minimal potential for particles or other potential contaminants to accumulate at the interview of the apertures 134, 154, 302 which is more likely when the geometry of the aperture through the adhesive layer is oval or other non-circular shape prevalent when the adhesive layer is not in a perforated non-sheet form.

While the foregoing is directed to embodiments of the present invention, other and further embodiments of the invention may be devised without departing from the basic scope thereof, and the scope thereof is determined by the claims that follow.

What is claimed is:

1. An adhesive material suitable for joining semiconductor chamber components, comprising:
an adhesive material having a Young's modulus lower than 300 psi.

2. The material of claim 1, wherein the adhesive material is a silicone based compound.

3. The material of claim 1, wherein the adhesive material is in sheet form.

4. The material of claim 1, wherein the adhesive material has a thermal stress less than 2 MPa.

5. The material of claim 1, wherein the adhesive material has a thermal conductivity between about 0.1 W/mK and about 5 W/mK.

6. The material of claim 1, wherein the thickness of the adhesive material is between about 100 μm and about 500 μm.

7. The material of claim 1, wherein the adhesive material is a preformed ring.

8. The material of claim 1, wherein the adhesive material has an elongation greater than 150 percent.

9. A semiconductor chamber component, comprising:
a first surface disposed adjacent a second surface; and
an adhesive material coupling the first surface to the second surface, wherein the adhesive material has a Young's modulus lower than 300 psi.

10. The chamber component of claim 9, wherein the adhesive material is a silicon based compound.

11. The chamber component of claim 9, wherein the first surface is ceramic and the second surface is metallic.

12. The chamber component of claim 9, wherein the first surface is a ceramic gas distribution plate and the second surface is a metallic conductive base plate and the adhesive material is arranged to define gas passages between the first and the second surface.

13. The material of claim 9, wherein the adhesive material has a thermal stress less than 2 MPa.

14. The material of claim 9, wherein the adhesive material has a thermal conductivity between about 0.1 W/mK and about 5 W/mK and a thickness between about 100 μm and about 500 μm.

15. The material of claim 9, wherein the adhesive material has an elongation greater than 150 percent.
